(19) United States
(12) Patent Application Publication
(10) Pub. No.: US 2024/0130086 A1
(43) Pub. Date: Apr. 18, 2024

(54) MULTIMODE IMMERSION COOLING

(71) Applicant: Nano and Advanced Materials Institute Limited, Hong Kong (HK)

(72) Inventors: Wai Chung LI, Hong Kong (HK); Chi Ho KWOK, Hong Kong (HK)

(21) Appl. No.: 18/393,724

(22) Filed: Dec. 22, 2023

Related U.S. Application Data
(63) Continuation-in-part of application No. 18/187,712, filed on Mar. 22, 2023.
(60) Provisional application No. 63/322,647, filed on Mar. 23, 2022.

(51) Int. Cl. H05K 7/20; C09K 5/04

(52) U.S. Cl. CPC H05K 7/20381; C09K 5/048; H05K 7/20236; H05K 7/20263; H05K 7/20272; H05K 7/20281; H05K 7/20318; H05K 7/20327

(57) ABSTRACT

A multimode immersion cooling system includes a first, single-phase immersion cooling mode and a second, two-phase immersion cooling mode. The system operates in a single phase mode and reserves a two-phase mode for peak energy consumption periods. A single thermal transfer fluid is used for both modes, remaining in a liquid phase in a first single-phase immersion cooling mode and vaporizing when the thermal transfer fluid temperature reaches its boiling point in a second two-phase immersion cooling mode. A heat exchanger extracts thermal energy from heated thermal transfer fluid in the single phase mode while a condenser cools vaporized thermal transfer fluid to condense the vapor during the second, two-phase immersion cooling mode. A controller determines whether the multimode immersion cooling system operates in the single-phase mode or the second two-phase mode, or both.

### CROSS-REFERENCE TO RELATED APPLICATIONS

The present application is a continuation-in-part of U.S. patent application Ser. No. 18/187,712 filed Mar. 22, 2023, which claims priority to U.S. Provisional Patent Application Ser. No. 63/322,647 filed Mar. 23, 2022, the disclosures of which are incorporated by reference herein.

### FIELD OF THE INVENTION

The present invention relates to immersion cooling systems and, more particularly, to a multimode immersion cooling system capable of using a single coolant in both a single-phase cooling operation and a two-phase cooling operation.

### BACKGROUND

Currently there are increasing demands in data-processing and storage capabilities required by data centers, with a large number of heat-generating electronic devices being placed in close proximity to one another. These high-power electrical systems generate considerable amounts of heat such that conventional air-based cooling systems (fans, air-conditioned environments) are unable to maintain a satisfactory operating temperature.

Immersion cooling is a recently-developed direct cooling technique in which heat is removed by circulating a cooling fluid in direct contact with heat-generating components placed in a cooling tank. The cooling fluid is cooled by one or more heat exchangers. Immersion cooling methods include single-phase and two-phase methods. For single-phase immersion cooling, the cooling fluid circulates across the heat-generating components with the heated cooling fluid being cooled by a heat exchanger with no phase change of the fluid during the process. For two-phase immersion cooling, the cooling fluid directly contacts the heat-generating components with excess heat generating a phase change to a vapor. The vaporized cooling fluid condenses via a heat exchanger and returns to the immersion cooling tank.

Single-phase immersion cooling generally employs a simpler system design than two-phase immersion cooling and experiences lower operating costs. This is due to loss of cooling fluid in two-phase immersion cooling systems in the vapor phase. There are also significant health and environmental concerns from vaporized two-phase immersion cooling fluids. Further, the vapor phase of the coolant may lead to device and system corrosion over time. However, two-phase immersion cooling, due to the heat expended during fluid vaporization, can cool devices operating at higher power than single-phase immersion cooling. This feature is particularly important during peak usage times in data centers.

Thus, there is a need in the art for improved immersion cooling systems that include the advantages of single-phase immersion cooling but include the greater cooling ability of two-phase immersion cooling systems, particularly during peak energy consumption periods resulting in the need for greater heat dissipation from the electronic devices being cooled. The present invention addresses this need.

### SUMMARY OF THE INVENTION

The present invention provides a multimode immersion cooling system having a first, single-phase immersion cooling mode and a second, two-phase immersion cooling mode. The system generally operates in a single phase mode while the two-phase mode may be reserved for peak energy consumption periods.

The multimode immersion cooling system includes a fluid-retaining container having space for accommodating an electronic device. A single thermal transfer fluid is positioned in the container such that the electronic device is at least partially in contact with the heat transfer fluid, the thermal transfer fluid remaining in a liquid phase in a first single-phase immersion cooling mode and vaporizing when the thermal transfer fluid temperature reaches its boiling point in a second two-phase immersion cooling mode.

A first single-phase mode heat removal sub-system communicates with the fluid-retaining container. The first heat removal sub-system includes one or more pumps and fluid-removal conduits communicating with the fluid-retaining container to remove heated thermal transfer fluid from the thermal transfer fluid positioned in the fluid-retaining container during the first single-phase immersion cooling mode. A heat exchanger extracts thermal energy from the heated thermal transfer fluid to form cooled thermal transfer fluid. One or more pumps and fluid-returning conduits communicating with the fluid-retaining container to return the cooled thermal transfer fluid to the fluid-retaining container.

A second two-phase mode heat-removal sub-system communicates with the fluid-retaining container. The two-phase heat-removal sub-system includes a condenser for contacting vapor from vaporized thermal transfer fluid such that vapor from vaporized thermal transfer fluid that contacts the condenser during the second, two-phase immersion cooling mode

A controller determines whether the multimode immersion cooling system operates in the first single-phase mode or whether the multimode immersion cooling system operates in the first single-phase mode and the second two-phase mode or whether the multimode immersion cooling system operates only in the second two-phase mode.

In a further aspect, the multimode immersion cooling system controller circulates a cooling fluid to the condenser during the second two-phase mode.

In a further aspect, the multimode immersion cooling system first heat exchanger sub-system includes a first conduit for transporting heated thermal transfer fluid from the fluid-retaining container.

In a further aspect, the multimode immersion cooling system first heat exchanger sub-system include a pump for transporting the heated thermal transfer fluid in the first conduit.

In a further aspect, the multimode immersion cooling system first conduit contacts one or more second conduits having one or more cooling fluids circulating through the one or more second conduits.

In a further aspect, the multimode immersion cooling system cooled thermal transfer fluid is returned to the fluid-retaining container via the first conduit or via one or more second conduits.

In a further aspect, the multimode cooling system includes a fluid injector having one more fluid injector outlets to distribute cooled thermal transfer fluid directly adjacent to one or more targeted heat-generating components of an electronic device.

In a further aspect, the multimode immersion cooling system condenser of the second heat exchanger sub-system includes one or more coils positioned in the fluid-retaining container having coil cooling fluid circulating therethrough.

In a further aspect, the multimode immersion cooling system circulating cooling fluid extracts heat from the thermal transfer fluid vapor to condense the thermal transfer fluid.

In a further aspect, the multimode immersion cooling system circulating cooling fluid transfers the extracted heat from the thermal transfer fluid to the atmosphere by a cooling tower.

In a further aspect, the multimode immersion cooling thermal transfer fluid has a thermal conductivity higher than 0.08 W m−1K−1, a dielectric constant (Dₖ) at 20-40 GHz less than 3.0, a heat of vaporization higher than 150 kJ kg−1 and includes a compound of formula (I) with elemental wt. % of fluorine atoms of less than 65%.

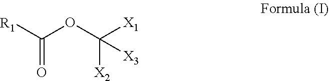

wherein X₁, X₂ and X₃ are independently selected from hydrogen, deuterium, halogen, —CH₃, —CF₃, —CHF₂, —OCH₃, —OCH₂CH₃, —OCH₂CF₃, —OCF₂CF₃, —CH₂CF₃, —CF₂CF₃, —CH₂CF₂CF₃, —CF₂CF₂CF₃, —OCH₂CF₂CF₃, —CH₂CH₂CF₃;

R₁ is selected from hydrogen, deuterium, halogen, C1-C10 alkyl, C3-C8 cycloalkyl, C2-C6 alkenyl, C3-C6 cycloalkenyl, C5-C7 (hetero)alkyl, C2-C6 alkyl ether with or with substitution by one or more fluorine atoms.

In a further aspect, the at least one of X₁, X₂ and X₃ is selected from hydrogen or deuterium and at least one of X₁, X₂ and X₃ is selected from —CF₃.

In a further aspect, R₁ is selected from a C1-C10 straight or branched chain alkyl group with or with substitution by one or more fluorine atoms.

In a further aspect, R₁ is selected from —CH₃, —CF₃, —CH₂CH₃ or —CH₂CF₃.

In a further aspect, a total number of fluorinated carbons in formula (I) is less than or equal to 3.

In a further aspect, the boiling point of the thermal transfer fluid ranges from 50° C. to 100° C.

In a further aspect, the thermal transfer fluid is non-flammable and possess no flash point.

In a further aspect, the density of the thermal transfer fluid is less than 1450 kg m⁻³.

In a further aspect, the thermal transfer fluid further comprises a density-reducing agent having a density less than 1200 kg m⁻³ in an amount less than or equal to 50 percent by weight selected from diethyl ether, petroleum ether, tetrahydrofuran, hexane, heptane, octane, cyclohexane, diglyme, 2-butanone, ethyl acetate, ethyl propionate, methyl propionate, hexane, heptane, octene, or dimethyl carbonate.

In a further aspect, the thermal transfer fluid further comprises a flame retardant in an amount less than or equal to 50 percent by weight selected from 1,1,1,2,3,3,3-heptafluoropropane, 1,1,1,2,2-pentafluoroethane, bromochlorodifluoromethane, bromotrifluoromethane, perfluoro(2-methyl-3-pentanone), perfluoro(2,4-dimethyl-3-pentanone), heptafluoro-1-methoxpropane, methyl nonafluoroisobutyl ether, ethyl nonafluoroi sobutyl ether, 3-methoxyperfluoro(2-methylbutane), 1,1,1,2,2,3,4,5,5,5-decafluoro-3-methoxy-4-(trifluoromethyl)pentane, perfluoro(4-methylpent-2-ene), trimethyl phosphate, triethyl phosphate, tripropyl phosphate, tributyl phosphate, triphenyl phosphate, trixylyl phosphate, or tris(1-chloro-2-propyl) phosphate

### BRIEF DESCRIPTION OF THE DRAWINGS

FIG. 1 is a schematic diagram of a multimode immersion cooling system according to an embodiment.

FIG. 2 is a schematic diagram of a heat exchanger for the multimode immersion cooling system of FIG. 1.

FIG. 3 is a schematic diagram of a fluid injector for the multimode immersion cooling system of FIG. 1

FIG. 4 is a schematic diagram of system A of the Examples.

FIG. 5A is a schematic diagram of system B of the Examples.

FIG. 5B is a schematic diagram of system C of the Examples.

FIG. 6 shows test results comparing systems A and B.

FIG. 7 shows test results comparing systems A and C for CPU TDP in CPU stress testing.

FIG. 8 shows test results for system C of the Examples using 3M Novec 7200 compared to the use of the thermal transfer fluid of the present invention in GPU stress test for hybrid cooling mode.

### DETAILED DESCRIPTION

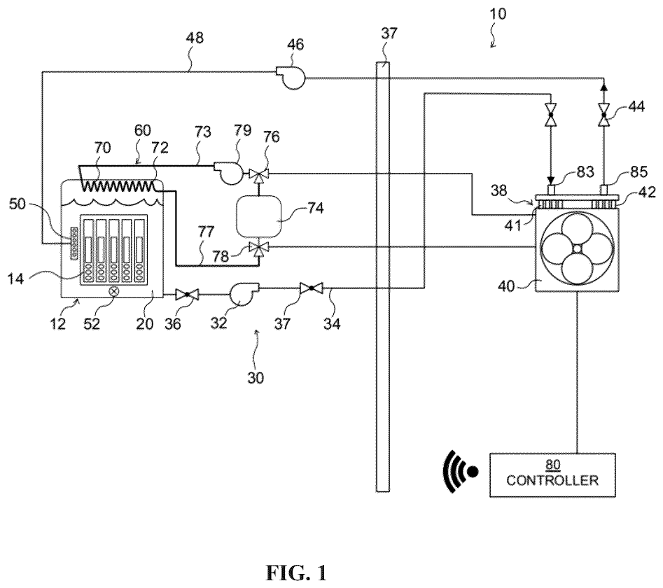

Turning to the drawings in detail, FIG. 1 depicts a multimode immersion cooling system 10 according to the present invention. The multimode immersion cooling system operates in a first, single-phase immersion cooling mode and a second, two-phase immersion cooling mode during pre-selected time periods or based on dynamically-measured operating conditions. However, it is contemplated that the primary mode of operation is a single-phase immersion cooling mode with the two-phase mode being a supplemental mode during peak operating periods.

Multimode immersion cooling system 10 includes a fluid-retaining container 12 having space for accommodating one or more electronic devices. In the diagram of FIG. 1, servers are depicted as the electronic devices, however, other devices such as energy storage devices (e.g., batteries) may also be selected. The system of FIG. 1 may be applied to a data center and used to cool a large number of servers; it may be a stand-alone system or part of a larger cooling network. The fluid-retaining container is typically a sealed container to prevent the escape of thermal transfer fluid.

A single thermal transfer fluid 20 is positioned in the fluid-retaining container 12 such that the electronic device is at least partially in contact with the thermal transfer fluid. A single thermal transfer fluid prevents problems that may arise when plural thermal transfer fluids are used. For example, the composition of coolant mixtures may change over time (for example, if the coolant mixture cannot form an azeotrope, with each component evaporating under its boiling point, a change in coolant composition may exist from time to time due to preferential vaporization of one of the coolants) during operation resulting in physical properties changes and safety issue if one of the coolants has a flash point. Although a single thermal transfer fluid is employed in the system of FIG. 1, various additives may be used with the thermal transfer fluid 20, as will be described in detail below. Although the present invention includes various novel coolants that may be used as the thermal transfer fluid, it is understood that other coolants may also be used in the multimode immersion cooling system of FIG. 1. In general, coolants that can operate in both single phase and two phase modes may be used as thermal transfer fluid 20.

The thermal transfer fluid remains in a liquid phase in a first single-phase immersion cooling mode and vaporizes when the thermal transfer fluid temperature reaches its boiling point in a second two-phase immersion cooling mode. The determination of the selective activation of the two-phase mode will be described in connection with the control sub-system. The thermal transfer fluid 20 may be contained in an “open bath” configuration, as depicted (although in a sealed container), in which the electronic devices 14 are directly immersed in fluid 20. Alternatively, the thermal transfer fluid may be contained in a direct liquid cooling (DLC) configuration in which the thermal transfer fluid circulates directly through channels or heat exchangers attached to the electronic devices 14. Thus, the electronics are not submerged in the fluid but a high degree of cooling may be achieved.

Multimode immersion cooling system 10 includes a first single-phase mode heat removal sub-system 30 communicating with the fluid-retaining container 12. The first heat removal sub-system includes one or more pumps 32 and fluid-removal conduits 34 communicating with the fluid-retaining container to remove heated thermal transfer fluid 20 from the thermal transfer fluid positioned in the fluid-retaining container 12 during the first single-phase immersion cooling mode. Valve 36 may be selectively actuated to control flow from container 12.

A heat exchanger 38 extracts thermal energy from the heated thermal transfer fluid 20 to form cooled thermal transfer fluid. As seen in the embodiment of FIG. 1, the heat exchanger may be a cooling tower 40 that is positioned outside exterior wall 37. Cooling towers are heat rejection devices that transfer waste heat to the atmosphere through the cooling of a water stream to a lower temperature. In a cooling tower system, heated thermal transfer fluid from container 12 is pumped to the top of the tower 40, where it is distributed over cool water in heat exchangers 38.

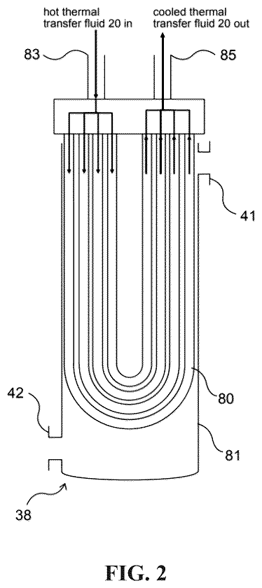

It is understood that the term “heat exchanger” in the context of the present multimode immersion cooling system is broadly applied to any device that can take the waste heat from the thermal transfer fluid 20 and produce cooled thermal transfer fluid 20 that can be returned to the fluid-retaining container 12. That is, any device may be used in which there is thermal transfer without the fluids mixing. The heat exchanger 38 of FIG. 2 depicts a shell and tube heat exchanger. This type of heat exchanger includes two main fluid paths; the primary path (“tubes” 80) carrying the heated thermal transfer fluid 20 (from container 12) and the secondary path (“shell” 81) carrying water as cooling fluid that completely surrounds the tubes 80. Other types of heat exchangers that may be used include double pipe, or various plate-based heat exchangers. The heated thermal transfer fluid enters the heat exchanger 38 through inlet 83 where it passes through tubes 80 and exits, having been cooled, through outlet 85. The shell cooling water from the cooling tower 40 enters heat exchanger 38 through inlet 41 and returns to the cooling tower 40 though outlet 42.

The shell water cooling fluid transfers waste heat to the external environment. This heated water is then distributed over fill or packing within the cooling tower 40. This allows the water to spread out and exposes it to the external environment. Simultaneously, air is drawn through the tower either by natural draft (chimney effect) or by using mechanical means (fans). As the air and water come into contact, a portion of the water evaporates, absorbing heat and cooling the rest of the water. The cooled water is then returned to an inlet 41 of heat exchanger 38 for use in cooling the thermal transfer fluid 20.

While cooling towers are a type of heat exchanger system for multimode immersion cooling system 10, other systems that may be used in the present invention to transfer waste heat include chillers (water-based or refrigerant-based), and dry coolers (air-based).

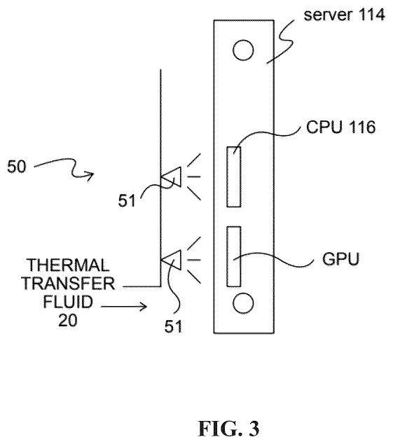

The same pump 32 or an additional pump 46 communicates with one or more fluid conduits 48 to return cooled thermal transfer fluid 20 to fluid-returning container 12. Within container 12, the thermal transfer fluid 20 may optionally be directly injected 50 into the vicinity of the electronic device 14 to enhance thermal transfer at the heat source. Direct injector 50 may be a spray nozzle or plenum fluid distributor over a large area of the electronic device, or any other wide-area fluid distribution system. Examples of direct injectors are depicted as FIG. 3. In the injector of FIG. 3, the electronic device 14 is depicted as a server; however, it is understood that the injector 50 may be used with any electronic device. Server 114 includes a CPU 116 and GPU 118. In server 114, these regions emit the greatest quantity of heat and therefore require an increased amount of cooling. When the cooled thermal transfer fluid 20 returns to fluid-retaining container 12, it may be injected by injector 50 directly to the CPU 116 and GPU 118 regions of the server as depicted in FIG. 3. As seen in FIG. 3, injector 50 may be a system of fluid injectors that includes multiple outlets 51. As seen by the arrows of FIG. 3, the injection directly to the hottest regions creates a thermal convection region that may be further circulated by one or more circulators 52.

To further enhance thermal fluid distribution within container 12, one or more circulators/mixers 52 may be positioned within the container to avoid “hot spots” near the equipment and to provide a more uniform temperature within thermal transfer fluid 20. This mixer may be, for example, magnetic-induced circulation motion or rotating blades for circulating the fluid. Fluid circulation reduces the accumulation of hot fluid adjacent to the electronic device 14.

Multimode immersion cooling system 10 further includes a second two-phase mode heat-removal sub-system 60 communicating with the fluid-retaining container 12. In the two-phase mode, the temperature of the thermal transfer fluid 20 reaches its boiling point, either due to an increased thermal load from electronic device 14 (e.g., servers during peak traffic periods) or due to shutting down or reducing the withdrawal of thermal transfer fluid into the first single-phase mode heat removal sub-system 30 through the control system (discussed in detail below). Thus the two-phase mode can be passively activated in the former condition or actively controlled in the latter condition. Further, the two-phase mode can operate simultaneously with the single-phase mode or on its own (as when the single-phase mode operation is reduced or eliminated).

The two-phase mode heat-removal sub-system 60 includes a condenser 70 for contacting vapor from vaporized thermal transfer fluid such that vapor from vaporized thermal transfer fluid that contacts the condenser during the second, two-phase immersion cooling mode. The condenser 70 is maintained at a temperature that is lower than the boiling point of the thermal transfer fluid. Typically this may be in the range from 20-28° C., for example, 25° C. Upon contacting condenser 70, the vaporized thermal transfer fluid condenses and returns to the reservoir of vaporized thermal transfer fluid. The heat released by condensation is transferred to the condenser 70.

Condenser 70 may have a variety of configurations, including serpentine coils, bundles of straight tubes, shell and tube, plates with fluid channels, microchannels, finned coils and cylindrical coils. Within the condenser, a cooling fluid 72 circulates. This fluid may be water, water mixed with another fluid such as glycol, a conventional fluorocarbon refrigerant, or other suitable cooling fluids. Depending upon the choice of cooling fluid, the cooling fluid 72 may be cooled in chiller 74 located within the same building as the multimode immersion cooling system or the chiller 74 may be positioned outside exterior wall 37. When the cooling fluid is water, it may be cooled using cooling tower 40 where the cooling water itself is cooled by evaporative heat exchange. Depending upon the desired temperature of the cooling fluid, a portion of the water may be sent to cooling tower 40 and a portion sent to cooling fluid chiller 74 through the use of three-way valves 76 and 78 which can dynamically select the amount of water to be routed to the chiller 74 or the cooling tower 40 through the use of a controller, to be discussed in further detail below. Optionally, chiller 74 may be eliminated and the same cooling system may be used for cooling both the thermal transfer fluid 20 and the cooling fluid 72. In yet another embodiment, separate cooling towers may be used for cooling thermal transfer fluid 20 and cooling fluid 72. Other cooling techniques for cooling thermal transfer fluid 20 and cooling fluid 72 may also be used.

To select the modes of the multimode immersion cooling system, a controller 80 determines whether the multimode immersion system operates in the first single-phase mode or whether the multimode immersion system operates in the first single-phase mode and the second two-phase mode or whether the multimode immersion cooling system operates in only the second two-phase mode. Controller 80 can dynamically select system operation modes based on electronic device power consumption levels as well as the temperature of thermal transfer fluid 20. Alternatively, or in connection with these measurements, controller 80 may factor in peak load times based on previous traffic patterns or current Internet traffic conditions when electronic devices 14 are servers. As discussed above, since it is contemplated that the primary mode of operation is the single-phase mode, the use of controller to supplement cooling with the two-phase cooling mode is the primary purpose of controller 80.

In support of controlling the operation mode of system 10, controller 80 can receive external information concerning internet operating conditions, power usage by electronic device 14, and Internet loads from wired or wireless communication with a data center command and control center or directly from the Internet itself. Various temperature monitoring points may be dispersed throughout system 10, including within thermal transfer fluid 20 in container 12, in conduit 34, at an exit point 85 of heat exchanger 38 following cooling in cooling tower 40, at the injection point of cooled fluid 50, and near electronic device 14. For the two-phase mode, temperature monitoring points may include those within condenser 70, at heated cooling fluid exit conduit 73, and at cooled cooling fluid return conduit 77.

Further, controller may control the amount of thermal transfer fluid 20 withdrawn from container 12 by means of selecting the operating volume for pump 32 and the flow amounts through valves 36 and 37. Similarly, for two-phase mode, the speed and temperature of the cooling liquid within condenser 70 may be controlled through pump 79 and three-way valves 76 and 78 which can determine the amount of cooling fluid routed to the cooling tower 40 or the chiller 74 or both. The temperature measurements may be through thermocouples or other measurement devices which relay measurements through wired or wireless connections to controller 80.

The controller 80 will typically include a communications interface for communication with the various temperature monitoring points and actuators (e.g., valves, pumps, etc.). The communications interface is connected (wireless or wired) to the Internet that monitors the real-time traffic to devices such as servers as well as the amount of electrical power that is being consumed by the servers for real-time knowledge of the instantaneous conditions.

Typically, the controller will include one or more algorithms that set thermal fluid temperature thresholds; if the temperature exceeds a certain threshold, the two-phase cooling mode may be activated. The controller may also correlate Internet traffic levels with potential increases in server load and heat generation, and, optionally determine peak operating times for servers based on historical data and predict future peak times from these patterns. By limiting two-phase mode to only peak operating times, loss of thermal transfer fluid by vapor escape, as well as environmental pollution from the lost vapor, is minimized. This also results in substantial cost savings. Although multimode system 10 operates primarily in a single-phase mode, the requirement that the thermal transfer fluid 20 be able to vaporize and condense in the two-phase mode places constraints on the thermal transfer fluid that are not present for purely single-phase immersion cooling systems. As such, the present invention includes an engineered thermal transfer fluid that has properties making it suitable for both single-phase and two-phase modes. That is cooling fluid 20 has both the high specific heat capacity needed for single-phase mode efficiency, increasing the amount of energy fluid 20 can absorb without a significant temperature increase, as well as a high heat of vaporization, increasing the amount of energy that can be absorbed by the fluid prior to its conversion to a vapor. Features of the thermal transfer fluid 20 as compared to conventional two-phase coolants is shown in Table 1, below:

TABLE 1

| | Two phase | Invention | | |
|---|---|---|---|---|
| | coolant | coolant | | Remarks |
| Boiling point | 50 | 70 | | Higher boiling point |
| (° C.) | | | | |
| Vapor pressure | 35 | 18 | (~50% lower) | Reduce the risk on |
| (kPa@25° C.) | | | | explosion |
| Heat of | 105 | 150 | (~50% higher) | Higher performance |
| vaporization | | | | in 2 phase |
| (kJ/kg) | | | | |
| Specific heat | 1100 | 1664 | (~50% higher) | Higher performance |
| capacity | | | | in single phase |
| (J/kgK) | | | | |

| | | | |
|---|---|---|---|
| GWP | >5000 | 59 | More Env. friendly |

Heat of vaporization (ΔHᵥₐₚ), also known as the latent heat or heat of evaporation, is the amount of energy (enthalpy) that must be added to a liquid substance to transform a quantity of that substance into a vapor phase. In some embodiments, according to the ASTM E2071 testing method disclosed “Standard Practice for Calculating Heat of Vaporization or Sublimation from Vapor Pressure Data”, the heat of vaporization of the thermal transfer fluid of the present disclosure is higher than 150 kJ kg⁻¹.

The thermal conductivity of a material is a measure of its ability to conduct heat. In both the single phase and two phase immersion cooling modes, it is important to have a large heat transfer rate from the hot electronic device to the thermal transfer fluid. In some embodiments, according to the ASTM D7896 testing method disclosed “Standard Test Method for Thermal Conductivity, Thermal Diffusivity, and Volumetric Heat Capacity of Engine Coolants and Related Fluids by Transient Hot Wire Liquid Thermal Conductivity Method”, the thermal transfer fluid 20 of the present disclosure has a thermal conductivity higher than 0.08 W m⁻¹K⁻¹.

The dielectric constant (Dₖ) is the permittivity of a material expressed as a ratio with the electric permittivity of a vacuum. It is a measure of the ability of a material to store electric energy in an electrical field. The signal loss is less when the electrical component is immersed in the low Dₖ materials. In some embodiments, the Dₖ values of the dielectric fluid at frequency from 10 MHz to 50 GHz was measured by N1601A Dielectric probe kit. The thermal transfer fluid 20 of the present disclosure has a dielectric constant (Dₖ) at 20-40 GHz less than 3.0.

The thermal transfer fluid includes a compound of formula (I):

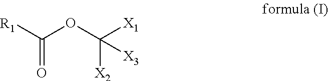

X₁, X₂ and X₃ are independently selected from hydrogen, deuterium, halogen, —CH₃, —CF₃, —CHF₂, —CH₂F, —OCH₃, —OCF₃, —OCH₂CH₃, —OCH₂CF₃, —OCF₂CF₃, —CH₂CF₃, —CF₂CF₃, —CH₂CF₂CF₃, —CF₂CF₂CF₃, —OCH₂CF₂CF₃, —CH₂CH₂CF₃.

In one embodiment, at least one of X₁, X₂ and X₃ is selected from hydrogen or deuterium and at least one of X₁, X₂ and X₃ is selected from —CF₃.

R₁ is selected from hydrogen, deuterium, halogen, C1-C10 alkyl, C3-C8 cycloalkyl, C2-C6 alkenyl, C3-C6 cycloalkenyl, C5-C7 (hetero)alkyl, C2-C6 alkyl ether with or with substitution by one or more fluorine atoms. In one embodiment, R₁ may be a C1-C10 straight or branched chain alkyl group with or with substitution by one or more fluorine atoms; examples of R₁ include —CH₃, —CF₃, —CH₂ CH₃ or —CH₂ CF₃.

In one embodiment, R₁ in formula (I) may be selected from hydrogen, deuterium, and the group consisting of: (1) halogen, may be selected from the group consisting of: fluorine, chlorine, bromine and iodine atom; (2) C1-C10 alkyl, further, may be selected from the following groups: methyl, ethyl, n-propyl, isopropyl, n-butyl, isobutyl, sec-butyl, tert-butyl, 2-methylbutyl, n-pentyl, n-hexyl, n-heptyl, n-octyl, 2-ethylhexyl, trifluoromethyl, pentafluoromethyl, 2,2,2-trifluoroethyl; (3) C3-C8 cycloalkyl, further, may be selected from the following groups: cyclopropyl, cyclobutyl, cyclopentyl cyclohexyl, cycloheptyl, cyclooctyl; (4) C2-C6 alkenyl, further, may be selected from the following groups: vinyl, propenyl, butenyl, pentenyl, hexenyl; (5) C3-C6 cycloalkenyl, further, may be selected from the following groups: cyclopentenyl , cyclohexenyl, cycloheptenyl, cyclooctenyl; (6) C2-C6 alkyl ether group, further, may be selected from the following groups: methoxyl, ethoxyl, n-propoxyl, isopropoxyl, n-butoxyl, isobutoxyl, or sec-butoxyl, tert-butoxyl or 2-methylbutoxyl.

In one embodiment, the compound described in formula (I) is a partially fluorinated compound with elemental wt. % of fluorine atoms of less than 65%.

In one embodiment, the total number of fluorinated carbons in formula (I) is less than or equal to 3.

In one embodiment, the elemental wt. % of fluorine atoms in formula (I) is less than 60%.

As used herein, “hetero” means an atom other than carbon (e.g., oxygen, nitrogen, or sulfur) that is bonded to a carbon chain (straight or branched or in a ring.

As used herein, the term “or” includes “and/or” unless the context dictates otherwise.

In the present invention, “substitution by one or more fluorine atoms” means that one or more hydrogen atoms on the carbon atoms in the substituent group is replaced by the fluorine atoms.

Specific suitable examples of the thermal transfer fluid according to the present disclosure are given below, but are not limited to:

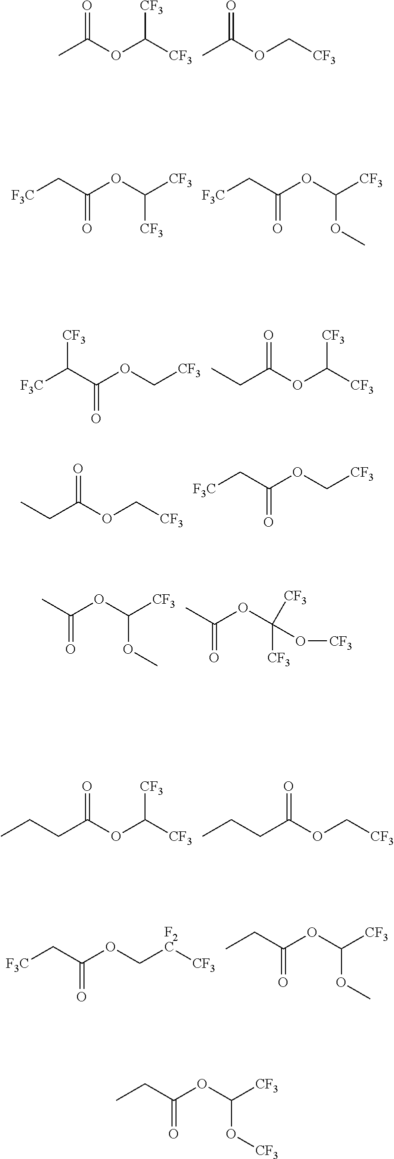

The thermal transfer fluid 20 can be used in the electronic device at a higher operation temperature than existing thermal transfer fluids. The development of computer chips, 5G technology and the increasing data processing power with increasing in number of severs and printed circuit board in data center also generated higher heat amount. Therefore, the thermal transfer fluids of the present invention are engineered to have a higher boiling point than conventional thermal transfer fluids. The testing method of the boiling point of the thermal transfer fluid is according to the ASTM D1120-08 “Standard Test Method for Boiling Point of Engine Coolants”. In some embodiments, the boiling point of the thermal transfer fluid 20 ranges from 50° C. to 100° C. In some embodiments, the thermal transfer fluid 20 of the present disclosure may have a boiling point between 50-100° C., or 60-90° C., or 65-80° C. A particularly useful boiling point is 70 which is found for a species described in the Examples.

In some embodiments, according to the ASTM D3828-16a (2021) testing method disclosed “Standard Test Methods for Flash Point by Small Scale Closed Cup Tester”, the fluorinated thermal transfer fluid 20 of the present disclosure is non-flammable and possess no flash point.

In addition to having a higher boiling point, it is desirable to lower the density of the thermal transfer fluid. Lower density fluids require less fuel to transport a certain weight of thermal transfer fluid and require less energy to pump and circulate in a data center environment. The testing method of the density of the thermal transfer fluid is according to the ASTM D1298-12b (2017) “Standard Test Method for Density, Relative Density, or API Gravity of Crude Petroleum and Liquid Petroleum Products by Hydrometer Method”. In some embodiments, the density of thermal transfer fluid 20 is less than 1450 kg m⁻³. This lower-density thermal transfer fluid may be achieved by employed a density-reducing agent having a density less than 1200 kg ⁻³ in an amount less than or equal to 50 percent by weight of the thermal transfer fluid. Examples of the density-reducing agent include diethyl ether, petroleum ether, tetrahydrofuran, hexane, heptane, octane, cyclohexane, diglyme, 2-butanone, ethyl acetate, ethyl propionate, methyl propionate, hexane, heptane, octene, or dimethyl carbonate.

Due to the nature of the data center environment, it may be desirable to include a flame retardant in an amount less than or equal to 50 percent by weight of the thermal transfer fluid. The flame retardant may be one or more of 1,1,1,2,3,3,3-heptafluoropropane, 1,1,1,2,2-pentafluoroethane, bromochlorodifluoromethane, bromotrifluoromethane, perfluoro(2-methyl-3-pentanone, perfluoro(2,4-dimethyl-3-pentanone), heptafluoro-1-methoxpropane, methyl nonafluoroisobutyl ether, ethyl nonafluoroisobutyl ether, 3-methoxyperfluoro(2-methylbutane), 1,1,1,2,2,3,4,5,5,5-decafluoro-3-methoxy-4-(trifluoromethyl)pentane, perfluoro(4-methylpent-2-ene), trimethyl phosphate, triethyl phosphate, tripropyl phosphate, tributyl phosphate, triphenyl phosphate, trixylyl phosphate, or tris(1-chloro-2-propyl) phosphate. Using a flame retardant, a fire can be extinguished within 5 seconds.

In view of the density-reducing additives and the flame retardant additives, the thermal transfer fluid may include the compound of formula (I) in an amount from 1 to 100 wt. % of the total weight of the thermal transfer fluid. In particular, the compound of formula (I) may be 25 to 80 wt. % based on the total weight of the thermal transfer fluid or, more particularly, 50 to 70 wt. %, based on the total weight of the thermal transfer fluid.

In an embodiment, the thermal transfer fluid of present disclosure is a liquid.

In another embodiment, the thermal transfer fluid of present disclosure is suspension.

In another embodiment, the thermal transfer fluid of present disclosure is a nano-fluid, in which the thermal transfer fluid is mixed with nanoparticles including carbon nanoparticles, multiwalled carbon nanotube (MWCNT), single wall carbon nanotube (SWCNT), graphene, graphene oxide, graphite, fullerene, diamond, silver nanoparticles, gold nanoparticles, copper nanoparticles, aluminum nanoparticles, iron nanoparticles, nickel nanoparticles, zinc nanoparticles, aluminum oxide (Al₂O₃) nanoparticles, titanium dioxide (TiO₂) nanoparticles, silicon nanoparticles, silicon carbide nanoparticles, boron nitride nanoparticles, silicon dioxide nanoparticles, or aluminum nitride nanoparticles.

Importantly, the cooling system and coolant of the present invention is compatible with the plastics, metals and rubbers as used in motherboards of electronic components that will be cooled by the system. That is, the coolant does not react with these materials or degrade them in any way. For example, the coolant is compatible to plastics including epoxy, ABS resin, PP, PE, PC, PTFE, and FR-4, as well as other plastics/polymers used in electronic components.

The thermal transfer fluid 20 is compatible with metals found in electronic devices such as copper, navy copper, Cupronickel, 304 stainless steel, 316 stainless steel, 6061 aluminum alloys, H68 brass, H62 brass, H59 brass, L245 alloy, lead tin alloys, or tin copper alloys. Further, the coolant does not react with or degrade semiconductor materials such as silicon, GaAs, GaN, indium-based semiconductors, and the dopants found within semiconductor devices.

The immersion cooling system coolant is also compatible with rubbers/sealants that are used in semiconductor device packaging and in housings that contain electronic devices such as servers. The coolant is compatible with silicone-based rubbers, nitrile rubbers, fluoro-rubbers, neoprene, EPDM, hydrogenated nitrile rubbers and polyurethane-based rubbers.

The thermal transfer fluid 20 used in the immersion cooling systems of the present invention may be made using relatively inexpensive fabrication techniques in which precursor materials are mixed and reacted under relatively low temperature conditions. In addition, the production method is environmentally friendly without using toxic and dangerous chemicals. Since, organic solvents are hazardous substances that require special treatment and disposal procedures, only water and water-soluble chemicals have been employed for the production method of the thermal transfer fluid in present disclosure. The thermal transfer fluid is readily separated from the reaction products and is easily purified using conventional distillation techniques.

### EXAMPLES

An immersion cooling system with a fluid-retaining container having space for accommodating an electronic device, a thermal transfer fluid positioned in the container such that the electronic device is in contact with the thermal transfer fluid and a heat exchanger communicating with the fluid-retaining container such that vapor from vaporization of the thermal transfer fluid contacts the heat exchanger. The thermal transfer fluid used is 1,1,1,3,3,3-hexafluoropropan-2-yl acetate (Example 1) or 75 wt. % 2,2,2-trifluoroethyl 3,3,3-trifluoropropanoate with 15 wt. % dimethyl carbonate as density reducing agent and 10 wt. % perfluoro(4-methylpent-2-ene) as a flame retardant (Example 2) or 80 wt. % 2,2,2-trifluoro-l-methoxyethyl acetate with 20 wt. % trimethyl phosphate as a flame retardant (Example 3) or NOVEC649 Engineered Fluid (Comparative Example 1) or NOVEC7000 Engineered Fluid (Comparative Example 2) or NOVEC7100 Engineered Fluid (Comparative Example 3).

### Preparation of Example 1

### Synthesis of 1, 1,1,3,3,3-hexafluoropropan-2-yl Acetate

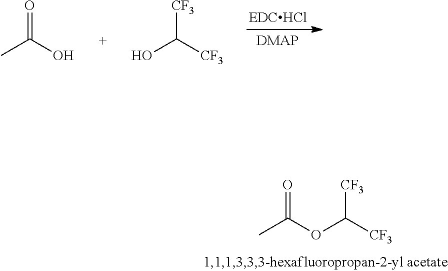

1-(3-Dimethylaminopropyl)-3-ethylcarbodiimide hydrochloride (EDC·HCl, CAS: 25952-53-8) (200 g, 1 eq) and 4-dimethylaminopyridine (DMAP, CAS: 1122-58-3) (38.3 g, 0.3 eq) was mixed into a 1000-mL round bottom flask and deionized water (500 mL) was added to dissolve the solid. Glacial acetic acid (CAS: 64-19-7) (75.4 g, 1.2 eq) and 1,1,1,3,3,3-hexafluoro-2-propanol (HFIP, CAS: 92066-1) (184.7 g, 1.05 eq) were then added slowly to the EDC·HCl and DMAP mixture to avoid the temperature rise. The reaction was stirred and was warmed up to 40° C. for 24 hours. Then, the reaction was settled down and two layers was separated. The upper aqueous layer was removed and the bottom organic layer was then distillated. The component which having the boiling point around 70° C. was collected. Yield: 132 g (60%). The product was analyzed and confirmed by NMR: ¹H NMR [500 MHz, CDCl₃]: δ 2.25 (s, 3H), 5.71-5.78 (septet, 1H) and ¹⁹F NMR [500 MHz, CDCl₃]: δ 73.62 (s, 6F).

### Preparation of Example 2

### Synthesis of 2,2,2-trifluoroethyl 3,3,3-trifluoropropanoate

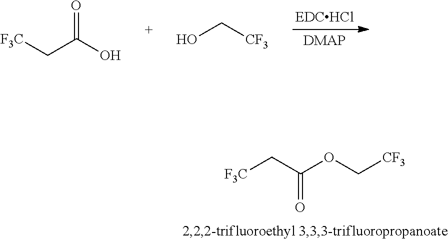 [SMILES: O=C(O)CC(F)(F)F ; OCC(F)(F)F ; O=C(CC(F)(F)F)OCC(F)(F)F]

EDC·HCl (200 g, 1 eq) and DMAP (38.3 g, 0.3 eq) was mixed into a 1000-mL round bottom flask and deionized water (500 mL) was added to dissolve the solid. 3,3,3-trifluoropropanoic acid (CAS: 2516-99-6) (147.5 g, 1.1 eq) and 2,2,2-trifluoroethanol (TFE, CAS: 75-89-8) (110 g, 1.05 eq) were then added slowly to the EDC·HCl and DMAP mixture to avoid a temperature rise. The reaction was stirred and was warmed up to 40° C. for 24 hours. Then, the reaction was settled down and two layers were separated. The upper aqueous layer was removed and the bottom organic layer was then distillated. The component having a boiling point below 80° C. was collected. Yield: 125.4 g (57%). The product was analyzed and confirmed by NMR: ¹H NMR [500 MHz, CDCl₃]: δ 2.77 (q, 2H), 4.60 (q, 2H) and ¹⁹F NMR [500 MHz, CDCl₃]: δ 74.86 (s, 3F), δ 92.27 (s, 3F).

Example 2 is 75 wt. % 2,2,2-trifluoroethyl 3,3,3-trifluoropropanoate with 15 wt. % dimethyl carbonate as a density reducing agent and 10 wt. % perfluoro(4-methylpent-2-ene) as a flame retardant.

### Preparation of Example 3

### Synthesis of 2,2,2-trifluoro-1-methoxyethyl Acetate

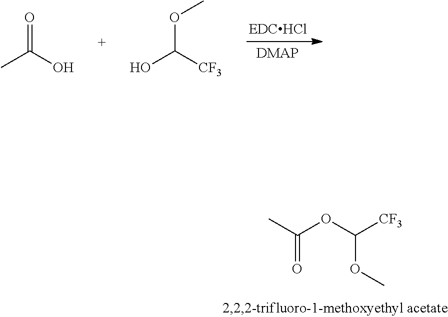

EDC·HCl (200 g, 1 eq) and DMAP (38.3 g, 0.3 eq) were mixed into a 1000-mL round bottom flask and deionized water (500 mL) was added to dissolve the solid. Glacial acetic acid (CAS: 64-19-7) (75.4 g, 1.2 eq) and trifluoroacetaldehyde methyl hemiacetal (CAS: 431-46-9) (142.5 g, 1.05 eq) were then added slowly to the EDC·HCl and DMAP mixture to avoid the temperature rise. The reaction was stirred and was warmed up to 40° C. for 24 hours. Then, the reaction was settled down and two layers was separated. The upper aqueous layer was removed and the bottom organic layer was then distillated. The component which having the boiling point below 80° C. was collected. Yield: 73.6 g (41%). The product was analyzed and confirmed by NMR: ¹H NMR [500 MHz, CDCl₃]: δ 2.03 (s, 3H), δ 3.40 (s, 3H), 7.28 (q, 1H) and ¹⁹F NMR [500 MHz, CDCl₃]: δ 77.11 (s, 3F).

Example 3 is 80 wt. % 2,2,2-trifluoro-l-methoxyethyl acetate with 20 wt. % trimethyl phosphate as a flame retardant.

The chemical structures of the density reducing agent and flame retardants are shown as follows:

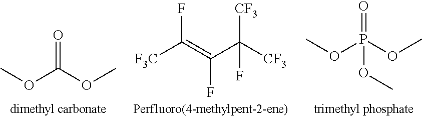

For those commercially-available engineered fluids, comparative examples CE1, CE2, and CE3 were purchased from 3M and were used directly without further treatment.

Table 2 shows the properties of the examples of thermal transfer fluid used and the comparison with the commercially-available fluids.

TABLE 1

| | CE1 | CE2 | CE3 | Example 1 | Example 2 | Example 3 |
|---|---|---|---|---|---|---|
| Partial/Fully | Fully | Partial | Partial | Partial | Partial | Partial |
| fluorinated | | | | | | |
| elemental wt. % of | 72.14% | 66.48% | 68.38% | 54.26% | 54.26% | 33.12% |
| fluorine atoms of | | | | | | |
| major component | | | | | | |
| Boiling pt. (° C.) | 49 | 34 | 61 | 70.6 | 75 | 72 |
| Density (kg/m³) | 1596 | 1400 | 1523 | 1418 | 1298 | 1327 |
| Flash point | No | No | No | No | No | No |
| Vapor Pressure | 40 | 65 | 27 | 19 | 17 | 15 |
| (kPa) | | | | | | |
| Dielectric | >40 kV | >40kV | >40 kV | >43.2 kV | >40 kV | >40 kV |
| strength | | | | | | |
| Dielectric | 1.8 | 7.4 | 7.4 | 5.18 | 5.03 | 4.89 |
| constant (@1 kHz) | | | | | | |
| Dielectric constant | 1.94 | 4.97 | 3.95 | 2.97 | 2.95 | 2.97 |
| (@20 GHz) | | | | | | |
| Dielectric constant | 2.01 | 3.56 | 3.06 | 2.75 | 2.83 | 2.66 |
| (@40 GHz) | | | | | | |
| Heat of vaporization | 88 | 142 | 112 | 150.47 | 167 | 175 |
| (kJ/kg) | | | | | | |
| Thermal | 0.06 | 0.075 | 0.07 | 0.08 | 0.09 | 0.08 |
| conductivity | | | | | | |
| (Wm⁻¹K⁻¹) | | | | | | |

As seen in Table 2, the thermal transfer fluid of the present disclosure offered a relatively lower elemental weight percentage of fluorine atom than the commercially-available product. While the fluid of the present invention obtains suitable boiling point range, no flash point, high dielectric strength, low dielectric constant with high heat of vaporization and thermal conductivity. In addition, the thermal transfer fluid of the present disclosure has a substantially higher boiling point, a high dielectric strength, a higher heat of vaporization and a substantially higher thermal conductivity than the prior art materials. As the heat of vaporization correlates directly to the efficiency of the heat transfer process for a two-phase immersion cooling system the present system demonstrates a higher capacity for heat transfer. Furthermore, in order to compare the partial fluorinated compounds, at both low frequency (1 kHz), high frequency (20 GHz) and very high frequency (40 GHz), the thermal transfer fluid of the present disclosure has the lower dielectric constant value than that of the commercial product CE2 and CE3.

### Example 4: Multimode System Tests

The system of FIG. 1 was used for testing server cooling as compared to conventional air cooling in a server casing and a conventional two-phase cooling system.

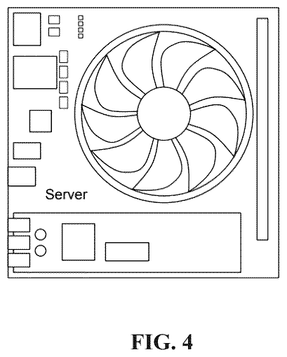

System A is a conventional cooling system as seen in FIG. 4. A CPU motherboard is mounted inside a computer casing and is air cooled. The thermal interface material (TIM) used between the CPU and a conventional heatsink with fan attached is a commercially-available gel product from Henkel, with a relatively high thermal conductivity of ˜10W/mK.

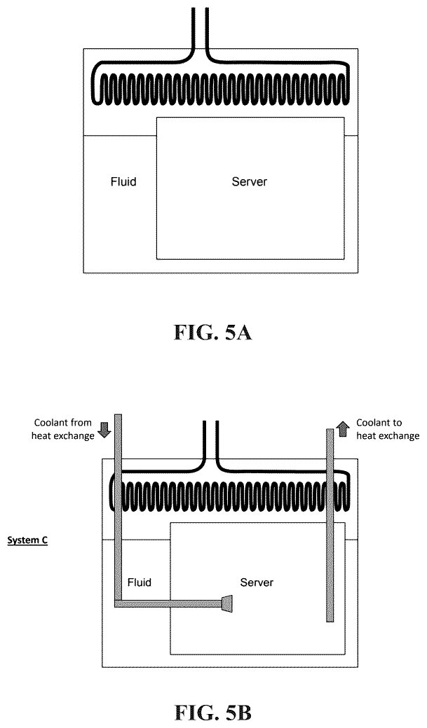

System B uses conventional two-phase immersion cooling as seen in the experimental system of FIG. 5A. The CPU is submerged in a dielectric fluid and a copper coil is used as a condenser. The copper coil has a second fluid (water) flowing within which forms another cooling circulation connected to a heat exchanger. In this system, the copper coil is only in contact with the vapor of the dielectric fluid, similar to the conventional two-phase immersion cooling system.

System C uses the system of the present invention as shown in the experimental system of FIG. 5B One set of copper tubes (placed horizontally) acts as the two-phase condensation mechanism and has a second fluid flowing within, which is circulated to a heat exchanger. Another set of copper tubes withdraws the liquid dielectric fluid within the container which is pumped to a heat exchanger to be cooled. The cooled dielectric fluid is then returned to the container and is directly distributed to the surface of the CPU through a nozzle. The coolant for system C is the thermal transfer fluid made in Example 1 (and, for comparison, the prior art 3M Novec 7200 coolant).

For the three systems tested, the same motherboard was used and the same dielectric fluid was used for systems B and C. The CPU used in the tests is Intel Core i9-12900K, having a base power of 125 W and can reach up to 241 W. To test and evaluate the differences between the three cooling systems applied, a testing software Intel® Extreme Tuning Utility (Intel® XTU) was used. CPU package temperature and the thermal design power (TDP) was recorded using the same software. CPU stress test was used as the testing method which the CPU was stressed until the temperature limit was reached (100° C. in this case) and thermal throttle was triggered. Despite all the CPU reaches the same temperature during the tests, the power consumed (TDP) would be different due to the cooling system's performance. In short, when the CPU is under load, a better cooling system applied enables the CPU to run at a relatively higher power at the same CPU temperature, thus better computing performances and vice versa.

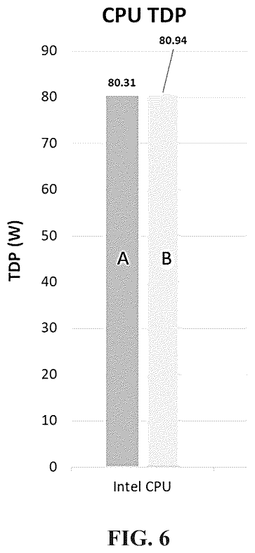

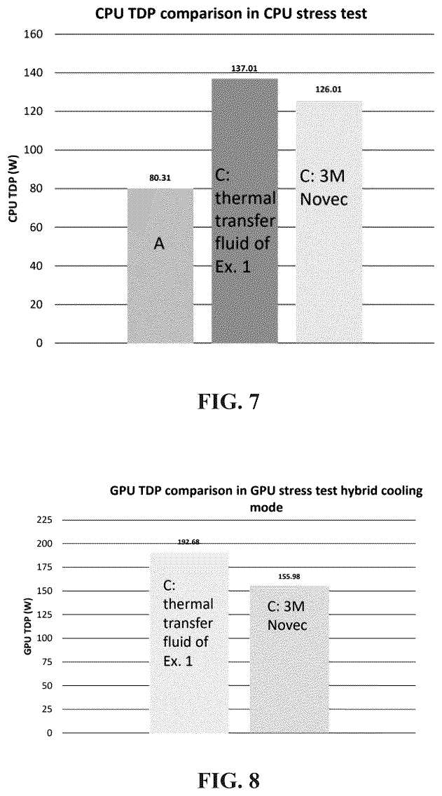

FIG. 6 shows a comparison of CPU cooling between systems A and B and system C. FIG. 7 shows the results of CPU stress tests for system A and system C. Table 3, below, shows a performance comparison between system C using coolant Novec 7200 (3M) and system B using 3M Novec 7200.

TABLE 3

| | | Invention | 3M Novec |
|---|---|---|---|
| | Testing standard | coolant | 7200 |
| Boiling point (° C.) | ASTM D1120 | 70 | 76 |
| Pour Point (° C.) | ASTM D5950 | −81 | −73 |
| Flash Point and | ASTM D3278 | Nil | Nil |
| fire point (° C.) | ASTM D92 | | |
| Autoignition | ASTM D659 | Nil | Nil |
| temperature (° C.) | | | |
| Dynamic viscosity (cSt) | ASTM D7042 | 0.63 | 0.41 |
| Specific heat capacity | ASTM E1269 | 1664 | 1220 |
| (J/kg-K) | | | |
| Latent heat of | ASTM E2071 | 150.5 | 119 |
| vaporization (kJ/kg) | | | |
| Thermal conductivity | ASTM D7896 | 0.08 | 0.07 |
| (W/mK) | | | |
| Vapor pressure 25° C. | ASTM D323 | 18 | 16 |
| (kPa) | | | |

As seen from FIG. 6 the immersion cooling of system B has greater ability to dissipate heat than the air cooling of system A. FIG. 7 shows that system C has greater cooling than system A and that system C using the thermal transfer fluid of Example 1 has a larger TDP than System C using 3M Novec 7200 coolants for CPU cooling in the CPU stress test.

FIG. 8 shows that, in hybrid cooling mode (that is, using both single and two-phase cooling), the cooling of the GPU in System C is greater using the thermal transfer fluids of Example 1 than the prior art 3M Novec 7200 coolants.

Table 3 shows that using system C in two-phase mode demonstrates a substantially greater specific heat capacity, latent heat of vaporization, and greater thermal conductivity.

As seen in Table 4, both 3M Novec 7200 and the thermal transfer fluids of the present invention show better cooling performance than air cooling. However, System C shows improved performance in TDP value for server CPU and GPU than the results for System B.

TABLE 4
Cooling Performance

| | | TDP value for CPU | TDP value for CPU | TDP value for GPU | TDP value for GPU |
|---|---|---|---|---|---|
| | TDP value | immersed in | immersed in | immersed in | immersed in |
| | for CPU | 7200 coolant | invention coolant | 7200 coolant | invention coolant |
| Conventional air cooling | 80.31 W | | | | |
| System A | | | | | |
| 2-phase system | | 80.13 W | 80.94 W | — | — |
| System B | | | | | |
| Multiple phase system | — | 126 W | 137 W | 156 W | 193 W |
| System C | | | | | |

As used herein, for ease of description, space-related terms such as “under”, “below”, “lower part”, “above”, “upper portion”, “lower portion”, “left side”, “right side”, and the like may be used herein to describe a relationship between one element or feature and another element or feature as shown in the figures. In addition to orientation shown in the figures, space-related terms are intended to encompass different orientations of the device in use or operation. A device may be oriented in other ways (rotated 90 degrees or at other orientations), and the space-related descriptors used herein may also be used for explanation accordingly. It should be understood that when a component is “connected” or “coupled” to another component, the component may be directly connected to or coupled to another component, or an intermediate component may exist.

As used herein, terms “approximately”, “basically”, “substantially”, and “about” are used for describing and explaining a small variation. When being used in combination with an event or circumstance, the term may refer to a case in which the event or circumstance occurs precisely, and a case in which the event or circumstance occurs approximately. As used herein with respect to a given value or range, the term “about” generally means in the range of ±10%, ±5%, ±1%, or ±0.5% of the given value or range. The range may be indicated herein as from one endpoint to another endpoint or between two endpoints. Unless otherwise specified, all the ranges disclosed in the present disclosure include endpoints. The term “substantially coplanar” may refer to two surfaces within a few micrometers (um) positioned along the same plane, for example, within 10 μm, within 5 μm, within 1 μm, or within 0.5 μm located along the same plane. When reference is made to “substantially” the same numerical value or characteristic, the term may refer to a value within ±10%, ±5%, ±1%, or ±0.5% of the average of the values.

Several embodiments of the present disclosure and features of details are briefly described above. The embodiments described in the present disclosure may be easily used as a basis for designing or modifying other processes and structures for realizing the same or similar objectives and/or obtaining the same or similar advantages introduced in the embodiments of the present disclosure. Such equivalent construction does not depart from the spirit and scope of the present disclosure, and various variations, replacements, and modifications can be made without departing from the spirit and scope of the present disclosure.

1. A multimode immersion cooling system for a first, single-phase immersion cooling mode and a second, two-phase immersion cooling mode comprising:
a fluid-retaining container having space for accommodating an electronic device;
a single thermal transfer fluid positioned in the container such that the electronic device is at least partially in contact with the thermal transfer fluid, the thermal transfer fluid remaining in a liquid phase in a first single-phase immersion cooling mode and vaporizing when the thermal transfer fluid temperature reaches its boiling point in a second two-phase immersion cooling mode;
a first single-phase mode heat removal sub-system communicating with the fluid-retaining container the first heat removal sub-system including:
one or more pumps and fluid-removal conduits communicating with the fluid-retaining container to remove heated thermal transfer fluid from the thermal transfer fluid positioned in the fluid-retaining container during the first single-phase immersion cooling mode;
a heat exchanger for extracting thermal energy from the heated thermal transfer fluid to form cooled thermal transfer fluid;
one or more pumps and fluid-returning conduits communicating with the fluid-retaining container to return the cooled thermal transfer fluid to the fluid-retaining container;
a second two-phase mode heat-removal sub-system communicating with the fluid-retaining container including:
a condenser for contacting vapor from vaporized thermal transfer fluid such that vapor from vaporized thermal transfer fluid that contacts the condenser during the second, two-phase immersion cooling mode;
a controller for determining whether the multimode immersion cooling system operates in the first single-phase mode or whether the multimode immersion cooling system operates in the first single-phase mode and the second two-phase mode or whether the multimode immersion cooling system operate only in the second two-phase mode.

2. The multimode immersion cooling system of claim 1, wherein the controller circulates a cooling fluid to the condenser during the second two-phase mode.

3. The multimode immersion cooling system of claim 1, wherein the first heat exchanger sub-system includes a first conduit for transporting heated thermal transfer fluid from the fluid-retaining container.

4. The multimode immersion cooling system of claim 3, wherein the first heat exchanger sub-system includes a pump for transporting the heated thermal transfer fluid in the first conduit.

5. The multimode immersion cooling system of claim 3, wherein the first conduit contacts one or more second conduits having one or more cooling fluids circulating through the one or more second conduits.

6. The multimode immersion cooling system of claim 5, wherein cooled thermal transfer fluid is returned to the fluid-retaining container via the first conduit or via one or more second conduits.

7. The multimode cooling system of claim 6 further comprising a fluid injector having one more fluid injector outlets to distribute cooled thermal transfer fluid directly adjacent to one or more targeted heat-generating components of an electronic device.

8. The multimode immersion cooling system of claim 1, wherein the condenser of the second heat exchanger sub-system includes one or more coils positioned in the fluid-retaining container, the one or more coils having coil cooling fluid circulating therethrough.

9. The multimode immersion cooling system of claim 8, wherein the circulating cooling fluid extracts heat from the thermal transfer fluid vapor to condense the thermal transfer fluid.

10. The multimode immersion cooling system of claim 9, wherein the circulating cooling fluid transfers the extracted heat from the thermal transfer fluid to the atmosphere by a cooling tower.

11. The multimode immersion cooling system of claim 1, wherein the thermal transfer fluid has a thermal conductivity higher than 0.08 W m⁻¹K⁻¹, a dielectric constant (Dₖ) at 20-40 GHz less than 3.0, a heat of vaporization higher than 150 kJ kg⁻¹ and includes a compound of formula (I) with elemental wt. % of fluorine atoms of less than 65%: 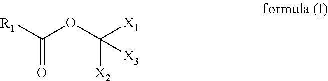
wherein X₁, X₂ and X₃ are independently selected from hydrogen, deuterium, halogen, —CH₃, —CF₃, —OCH₃, —OCH₂CH₃, —OCH₂CF₃, —OCF₂CF₃, —CH₂CF₃, —CF₂CF₃, —CH₂CF₂CF₃, —CF₂CF₂CF₃, —OCH₂CF₂CF₃, —CH₂ CH₂ CF₃;
R₁ is selected from hydrogen, deuterium, halogen, C1-C10 alkyl, C3-C8 cycloalkyl, C2-C6 alkenyl, C3-C6 cycloalkenyl, C5-C7 (hetero)alkyl, C2-C6 alkyl ether with or with substitution by one or more fluorine atoms.

12. The multimode cooling system of claim 11, wherein at least one of X₁, X₂ and X₃ is selected from hydrogen or deuterium and at least one of X₁, X₂ and X₃ is selected from —CF₃.

13. The multimode immersion cooling system of claim 11, wherein R₁ is selected from a C1-C10 straight or branched chain alkyl group with or with substitution by one or more fluorine atoms.

14. The multimode immersion cooling system of claim 11, wherein R₁ is selected from —CH₃, —CF₃, —CH₂CH₃ or —CH₂CF₃.

15. The multimode immersion cooling system of claim 11, wherein a total number of fluorinated carbons in formula (I) is less than or equal to 3.

16. The multimode immersion cooling system of claim 11, wherein the boiling point of the thermal transfer fluid ranges from 50° C. to 100° C.

17. The multimode immersion cooling system of claim 11, wherein the thermal transfer fluid is non-flammable and possess no flash point.

18. The multimode immersion cooling system of claim 11, wherein the density of the thermal transfer fluid is less than 1450 kg m⁻³.

19. The multimode immersion cooling system of claim 11, wherein the thermal transfer fluid further comprises a density-reducing agent having a density less than 1200 kg m⁻³ in an amount less than or equal to 50 percent by weight selected from diethyl ether, petroleum ether, tetrahydrofuran, hexane, heptane, octane, cyclohexane, diglyme, 2-butanone, ethyl acetate, ethyl propionate, methyl propionate, hexane, heptane, octene, or dimethyl carbonate.

20. The multimode immersion cooling system of claim 11, wherein the thermal transfer fluid further comprises a flame retardant in an amount less than or equal to 50 percent by weight selected from 1,1,1,2,3,3,3-heptafluoropropane, 1,1,1,2,2-pentafluoroethane, bromochlorodifluoromethane, bromotrifluoromethane, perfluoro(2-methyl-3-pentanone), perfluoro(2,4-dimethyl-3-pentanone), heptafluoro-1-methoxpropane, methyl nonafluoroisobutyl ether, ethyl nonafluoroisobutyl ether, 3-methoxyperfluoro(2-methylbutane), 1,1,1,2,2,3,4,5,5,5-decafluoro-3-methoxy-4-(trifluoromethyl)pentane, perfluoro(4-methylpent-2-ene), trimethyl phosphate, triethyl phosphate, tripropyl phosphate, tributyl phosphate, triphenyl phosphate, trixylyl phosphate, or tris(1-chloro-2-propyl) phosphate.
